(19) United States
(12) Patent Application Publication
(10) Pub. No.: US 2009/0079052 A1
(43) Pub. Date: Mar. 26, 2009

(54) Semiconductor package, apparatus and method for manufacturing the semiconductor package, and electronic device equipped with the semiconductor package

(75) Inventor: Cheul-Joong Youn, Seoul (KR)

Correspondence Address: MILLS & ONELLO LLP, ELEVEN BEACON STREET, SUITE 605, BOSTON, MA, 02108, US

(73) Assignee: Samsung Electronics Co., Ltd, Suwon-si (KR)

(21) Appl. No.: 12/284,328

(22) Filed: Sep. 19, 2008

(30) Foreign Application Priority Data
Sep. 20, 2007 (KR) 10-2007-0095915

(51) Int. Cl. H01L 23/02; H01L 21/00

(52) U.S. Cl. 257/678; 438/113; 257/E23.18

(57) ABSTRACT

Provided is a semiconductor package which includes a substrate that includes a chip region having an active surface and an inactive surface, and a dicing region having an active surface and an inactive surface; connection terminals disposed on the active surface that belongs to the chip region; a first molding layer that covers the active surface that belongs to the chip region and exposes a portion of the connection terminals; and a second molding layer that covers the active region that belongs to the dicing region and is disposed along the dicing region and has a different surface shape from the first molding layer so as to recognize a dicing line dividing the chip regions. The semiconductor package is manufactured using an apparatus for manufacturing a semiconductor package having a mold surface that coincides to surface shapes of the first and second molding layers.

### CROSS-REFERENCE TO RELATED APPLICATIONS

This U.S. non-provisional patent application claims priority under 35 U.S.C. §119 to Korean Patent Application No. 10-2007-0095915, filed in the Korean Intellectual Property Office on Sep. 20, 2007, the entire contents of which are hereby incorporated by reference.

### BACKGROUND OF THE INVENTION

The present invention relates to a semiconductor device, and more particularly, to a semiconductor package, an apparatus and a method for manufacturing the semiconductor package, and an electronic device equipped with the semiconductor package.

As electronic devices have been developed to be small, highly functional, slim and lightweight, a wafer level package has been gaining attention. The wafer level package has an advantage capable of embodying a chip-sized package through dicing after interconnections and external terminals are formed at a wafer level without using an interposer such as an existing lead frame or an existing printed circuit board. Since the wafer level package is a technology capable of high productivity and cost reduction, a requirement for developing this technology will increase.

### SUMMARY OF THE INVENTION

According to a first aspect, the present invention is directed to a wafer level semiconductor package. The wafer level semiconductor package may include a substrate having an active surface and an inactive surface opposed to the active surface, the substrate including a chip region and a dicing region. A connection terminal is disposed on the active surface in the chip region. A first molding layer covers the active of the chip region and exposes a portion of the connection terminal. A second molding layer covers the active region of the dicing region and has a different surface shape from the first molding layer so as to recognize a dicing line dividing the chip region.

In one embodiment, the first molding layer includes a first top surface having a flat shape and the second molding layer includes a second top surface having an irregular shape.

In one embodiment, the second top surface is higher than the first top surface. In one embodiment, the second top surface is as high as or lower than a top surface of the connection terminal. In one embodiment, the first top surface is lower than the top surface of the connection terminal.

In one embodiment, the second molding layer includes protrusions higher than the first top surface and a groove disposed between the protrusions. In one embodiment, the groove constitutes the dicing line.

In one embodiment, the package further comprises a third molding layer covering the inactive surface.

According to another aspect, the present invention is directed to a chip level semiconductor package. The chip level semiconductor package may include a substrate including an active surface and an inactive surface; a connection terminal disposed on the active surface; a first molding layer that is formed on the active surface and is lower than the connection terminal; and a second molding layer that is formed on an outside active surface of the substrate and surrounds the connection terminal and is higher than the first molding layer.

In one embodiment, a height of the second molding layer is equal to or smaller than a height of the connection terminal.

In one embodiment, the second molding layer is disposed on an edge of the substrate to constitute a wall surrounding the connection terminal.

In one embodiment, the package further comprises a third molding layer covering the inactive surface.

The invention is also directed to an electronic device including the semiconductor package.

According to another aspect, the present invention is directed to a method of manufacturing a semiconductor package. The method may include providing a substrate having an active surface and an inactive surface opposed to the active surface, the substrate comprising a chip region and a dicing region; forming a connection terminal on the active surface that belongs to the chip region; forming a first molding layer exposing a portion of the connection terminal on the active surface that belongs to the chip region; and forming a second molding layer having a different surface shape from the first molding layer so as to recognize a dicing line dividing the chip region on the active region that belongs to the dicing region.

The invention is also directed to an electronic device including the semiconductor package manufactured using the method of the invention.

In one embodiment, forming the first and second molding layers are simultaneously performed.

In one embodiment, forming the first molding layer includes forming a molding layer with a flat top surface lower than a top surface of the second molding layer.

In one embodiment, forming the second molding layer includes forming a molding layer with an irregular top surface higher than a top surface of the first molding layer. In one embodiment, forming the second molding layer includes forming a molding layer with protrusions higher than the first molding layer and a groove defining a dicing line between the protrusions. In one embodiment, forming the second molding layer includes forming the protrusions to be as high as or lower than the connection terminal.

In one embodiment, the method further comprises dicing the substrate along the dicing region.

The present invention is also directed to an electronic device including the semiconductor package manufactured using the method of the invention.

In one embodiment, dicing the substrate comprises: dividing the substrate into a plurality of unit substrates each having the chip regions; and dividing the second molding layer along the dicing regions to form a supporter surrounding the chip region outside the plurality of respective unit substrates.

In one embodiment, the method further comprises a third molding layer covering the inactive surface.

According to another aspect, the present invention is directed to an apparatus for manufacturing a semiconductor package. The apparatus for manufacturing a semiconductor package may include a first mold die that includes a first recessed inner face that constitutes a first cavity into which a first molding material is provided and includes a flat side and an irregular side, wherein a first tape is provided on the first recessed inner face; and a second mold die coupled to the first molding die. In one embodiment, a semiconductor package is disposed between the first and second mold dies to form a molding layer on a first surface of the semiconductor package.

The invention is also directed to an electronic device including the semiconductor package manufactured using the apparatus of the invention.

In one embodiment, a semiconductor package dividing into a chip region and a dicing region is interposed between the first and second mold dies so that a first molding layer having a flat top surface is formed on an active surface of the chip region by the flat side of the first recessed inner face, and a second molding layer having an irregular top surface higher than the first molding layer is formed on an active surface of a dicing region by the irregular side of the first recessed inner face.

In one embodiment, the apparatus further comprises a third mold die attachable to the first mold die, wherein the first recessed inner face is disposed on the third mold die.

In one embodiment, the first mold die further comprises an attaching portion into which the third mold die is fixedly inserted.

In one embodiment, the irregular side includes a groove aligned with the dicing region of the semiconductor package.

In one embodiment, a connection terminal is included in the chip region of the semiconductor package and a portion of the connection terminal sinks into the first tape.

In one embodiment, the first tape has a thickness equal to or greater than a sinking depth of the connection terminal.

In one embodiment, a connection terminal is included in the chip region of the semiconductor package and the irregular side further includes a dent into which a portion of the connection terminal sinks.

In one embodiment, the first tape has a thickness that is smaller than a depth of the dent.

In one embodiment, the depth of the dent is equal to or lower than a depth of the groove.

In one embodiment, the first mold die includes a first vacuum hole absorbing the first tape.

In one embodiment, the apparatus further comprises a first injection portion injecting the first molding material to the first cavity.

In one embodiment, the second mold die further includes a second recessed inner face into which a second tape is provided and constitutes a second cavity into which a second molding material is provided.

The invention is also directed to an electronic device including the semiconductor package manufactured using the apparatus of the invention.

In one embodiment, a third molding layer is formed on an inactive surface opposed to the active surface of the semiconductor package by the second recessed inner face.

In one embodiment, the second tape has a thickness equal to or smaller than the thickness of the first tape.

In one embodiment, the second mold die further includes a second vacuum hole absorbing the second tape.

In one embodiment, the apparatus further comprises a first injecting portion providing the first molding material to the first cavity and a second injecting portion providing the second molding material to the second cavity.

In one embodiment, at least one of the first and second mold dies can be heated.

According to another aspect, the present invention is directed to a method of manufacturing a semiconductor package. The method of manufacturing a semiconductor package may include providing a first mold die that includes a first recessed inner face constituting a first cavity into which a first molding material is provided, the first recessed inner face having a flat side and an irregular side; providing a second mold die vertically facing the first mold die; providing a semiconductor package between the first and second mold dies; providing the first molding material to the first cavity; forming a first molding layer that has a top surface of a uniform height on an active surface of a chip region of the semiconductor package through the first molding material provided into the flat side of the first recessed inner face; and forming a second molding layer having a top surface that has an irregular height and is higher than the first molding layer on an active surface of a dicing region of the semiconductor package through the first molding material provided into the irregular side of the first recessed inner face.

The invention is also directed to an electronic device including the semiconductor package manufactured using the method of the invention.

In one embodiment, forming the second molding layer comprises forming a molding layer of a concavo-convex shape including protrusions that is higher than the first molding layer and a groove defining a dicing line between the protrusions.

In one embodiment, the method further comprises providing a first tape that can be bent along the flat and irregular sides to the first recessed inner face.

In one embodiment, the second mold die further comprises a second recessed inner face constituting a second cavity into which a second molding material is provided.

In one embodiment, the method further comprises: providing the second molding material to the second cavity; and forming a third molding layer on an inactive surface of the semiconductor package. The invention is also directed to an electronic device including the semiconductor package manufactured using the method of the invention.

In one embodiment, the method further comprises: providing a first tape that can be bent along the flat and irregular sides to the first recessed inner face; and providing a second tape to the second recessed inner face.

In one embodiment, a thickness of the second tape is equal to or smaller than a thickness of the first tape.

### BRIEF DESCRIPTION OF THE FIGURES

The foregoing and other features and advantages of the invention will be apparent from the more particular description of preferred aspects of the invention, as illustrated in the accompanying drawings in which like reference characters refer to the same parts throughout the different views. The drawings are not necessarily to scale, emphasis instead being placed upon illustrating the principles of the invention. In the drawings, the thickness of layers and regions are exaggerated for clarity.

FIGS. 1A to 1C are cross-sectional views illustrating a method of manufacturing a semiconductor package in accordance with a first embodiment of the present invention.

FIG. 2A is a top plan view of a semiconductor package embodied by a semiconductor manufacturing method in accordance with a first embodiment of the present invention.

FIG. 2B is a perspective view of a semiconductor package embodied by a semiconductor manufacturing method in accordance with a first embodiment of the present invention.

FIGS. 3A and 3B are cross-sectional views of a mount example of a semiconductor package embodied by a semiconductor manufacturing method in accordance with a first embodiment of the present invention.

FIG. 4A is a cross-sectional view of an apparatus for manufacturing a semiconductor package in accordance with a first embodiment of the present invention.

FIG. 4B is a cross-sectional view illustrating a method of molding a semiconductor package using an apparatus for manufacturing a semiconductor package in accordance with a first embodiment of the present invention.

FIG. 4C is a cross-sectional view of an apparatus for manufacturing a semiconductor package in accordance with a second embodiment of the present invention.

FIG. 5A is a cross-sectional view of an apparatus for manufacturing a semiconductor package in accordance with a third embodiment of the present invention.

FIG. 5B is a cross-sectional view illustrating a method of molding a semiconductor package using an apparatus for manufacturing a semiconductor package in accordance with a third embodiment of the present invention.

FIG. 5C is a cross-sectional view of an apparatus for manufacturing a semiconductor package in accordance with a fourth embodiment of the present invention.

FIGS. 6A to 6C are cross-sectional views illustrating a method of manufacturing a semiconductor package in accordance with a second embodiment of the present invention.

FIG. 7A is a cross-sectional view of an apparatus for manufacturing a semiconductor package in accordance with a fifth embodiment of the present invention.

FIG. 7B is a cross-sectional view of an apparatus for manufacturing a semiconductor package in accordance with a sixth embodiment of the present invention.

FIG. 8A is a cross-sectional view of an apparatus for manufacturing a semiconductor package in accordance with a seventh embodiment of the present invention.

FIG. 8B is a cross-sectional view of an apparatus for manufacturing a semiconductor package in accordance with an eighth embodiment of the present invention.

FIGS. 9A and 9B are perspective views of electronic devices equipped with a semiconductor package in accordance with example embodiments of the present invention.

### DETAILED DESCRIPTION OF PREFERRED EMBODIMENTS

The present invention now will be described more fully hereinafter with reference to the accompanying drawings, in which embodiments of the invention are shown. This invention may, however, be embodied in many different forms and should not be construed as limited to the embodiments set forth herein.

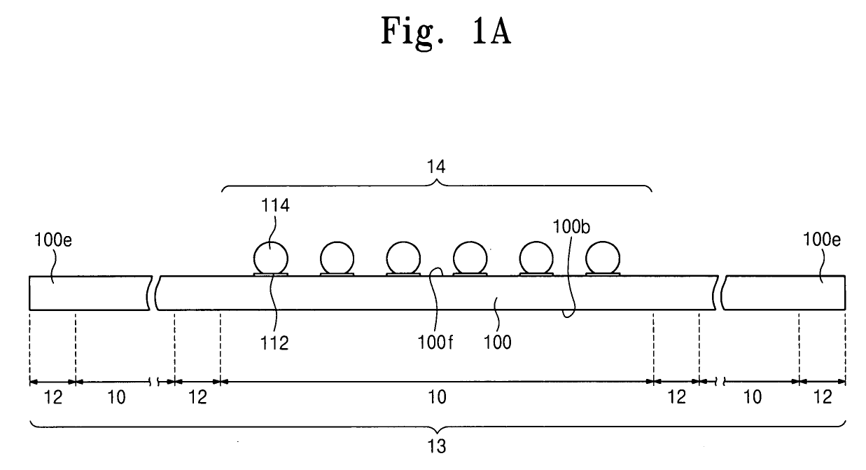

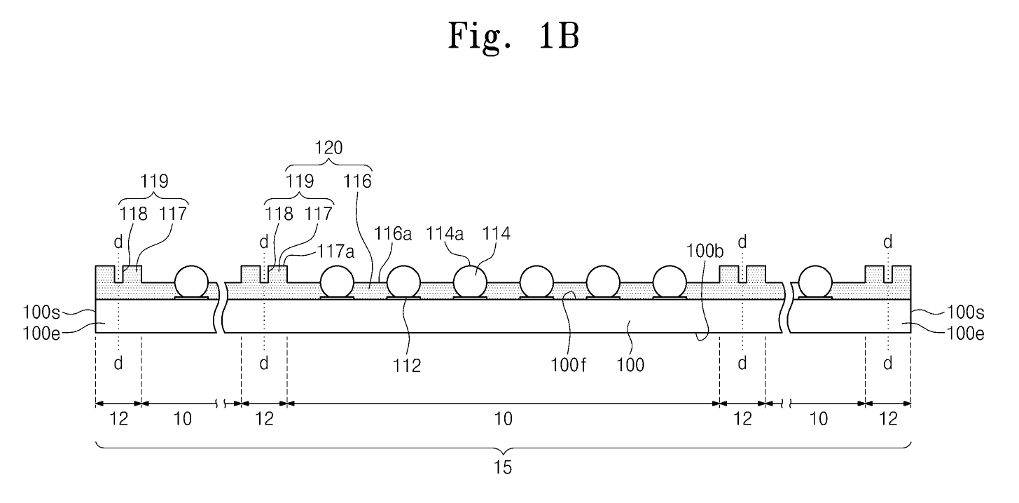

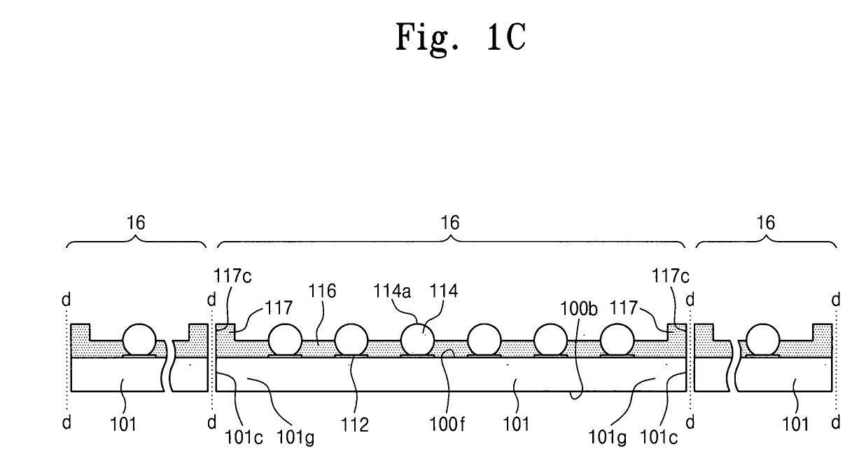

FIGS. 1A to 1C are cross-sectional views illustrating a method of manufacturing a semiconductor package in accordance with a first embodiment of the present invention.

Referring to FIG. 1A, a wafer unit substrate 100 such as a silicon wafer is provided. The substrate 100 includes an active surface 100f on which circuit patterns are formed and an inactive surface 100b which is opposite to the active surface 100f. The substrate 100 may be divided into a chip region 10 and a dicing region 12 dividing the chip region 10. There may be no the dicing region 12 in an outermost region of the substrate 100.

A pad 112 electrically connected to a circuit pattern may be formed on the active surface 100f and a connection terminal 114 such as a solder ball electrically connected to the pad 112 may be formed. A plurality of the pads 112 and the connection terminals 114 may be formed on the active surface 100f. As a result, a wafer unit semiconductor package, that is, a wafer level package 13 may be accomplished. If the substrate 100 is cut along the dicing region 12, the wafer level package 13 may be divided into a plurality of chip unit semiconductor packages 14.

The wafer level package 13 may be packaged in a state that the substrate 100 is not molded, that is, in a bare wafer state. When the wafer level package 13 consisted of the substrate 100 of a bare wafer state is tested or mounted on a board, it may be easily damaged or broken by an external shock. In particular, damage of the active surface 100f may easily lead to fatal damage of the wafer level package 13. The above phenomenon may also happen in the chip unit package 14. Thus, it is preferable that a molding process is further performed so as to protect the active surface 100f.

Referring to FIG. 1B, a molding layer 120 may be formed on the active surface 100f of the substrate 100. The molding layer 120 may comprise an epoxy molding compound (EMC). The molding layer 120 may include a first molding layer 116 formed on the active surface 100f of the chip region 10 and a second molding layer 119 formed on the active surface 110f of the dicing region 12. The first molding layer 116 protects the active surface 100f of the chip region 100, and firmly fixes the connection terminal 114 to prevent the connection terminal 114 from being separated. When the first molding layer 116 is formed, an upper portion of the connection terminal 114 protrudes upwardly from a top surface 116a of the first molding layer 116. The first molding layer 116 may be formed to be flat. The second molding layer 119 protects the active surface 100f of the dicing region 12 and serves as a mark to easily recognize the dicing region 12 from an outside. Thus, the present invention may not need a laser marking process to indicate the dicing region 12. The second molding layer 119 may be formed to have a concave-convex shape to serve as a mark of the dicing region 12. That is, if the second molding layer 119 can be distinguished from the first molding layer 116 by appearance, the second molding layer 119 can be formed in any shape.

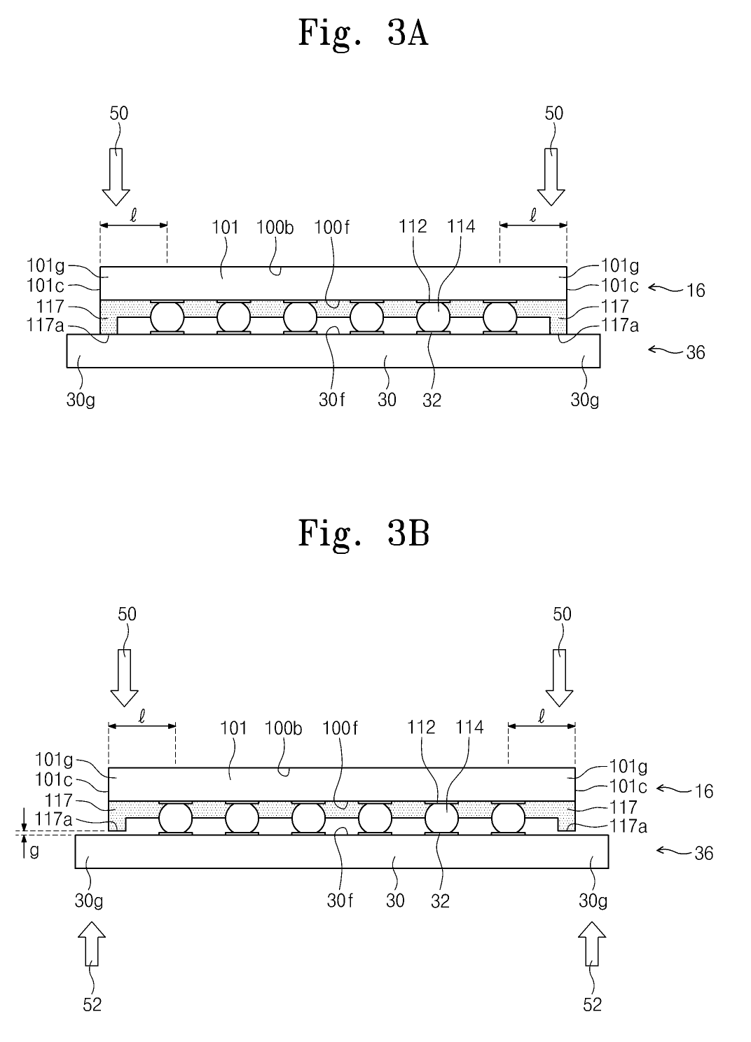

For example, the first molding layer 116 may be formed to be flat. Unlike the first molding layer 116, the second molding layer 119 may be formed to have two protrusions 117 of a square shape protruded upwardly from the top surface 116a of the first molding layer 116 and a groove 118 of a square shape recessed between the two protrusions 117. The groove 118 serves as a dicing line d-d. The protrusion 117, as will be described later referring to FIG. 3A, serves as a supporter of a chip unit semiconductor package 16. A height of the protrusion 117 may be arbitrary. For example, a top surface 117a of the protrusion 117 may be even with or lower than the top surface 114a of the connection terminal 114. The protrusion 117 and/or the groove 118 of the second molding layer 119 may also be formed to have different shapes such as a hemisphere shape, a trapezoid shape or a triangle shape.

The second molding layer 119 may be formed on the active surface 100f of the outermost portion 100e of the substrate 100. The second molding layer 119 of outermost portion 100e may be formed to have a concave-convex shape including the protrusions 117 and the groove 118, thereby forming a dicing line d-d. Alternatively, the second molding layer 119 of outermost portion 100e may be formed to have only the protrusion 117, thereby not forming the dicing line d-d. The molding layer 120 may be formed or may not be formed on the outermost lateral side 100s of the substrate 100.

According to the molding process described above, since the active surface 100f that can be easily damaged by an external shock or particles is protected by the molding layer 120, a molded wafer level package 15 that is not broken or damaged during a process is accomplished. The substrate 100 of the molded wafer level package 15 may be not bent or bent to a minimum by the molding layer 120. Further, when the molded wafer level package 15 is mounted on a printed circuit board (PCB) or an electrical module, the second molding layer 119 can absorb or disperse a stress applied to the molded wafer level package 15 or the connection terminal 114. Thus, a mechanical durability of the molded wafer level package 15 may be improved.

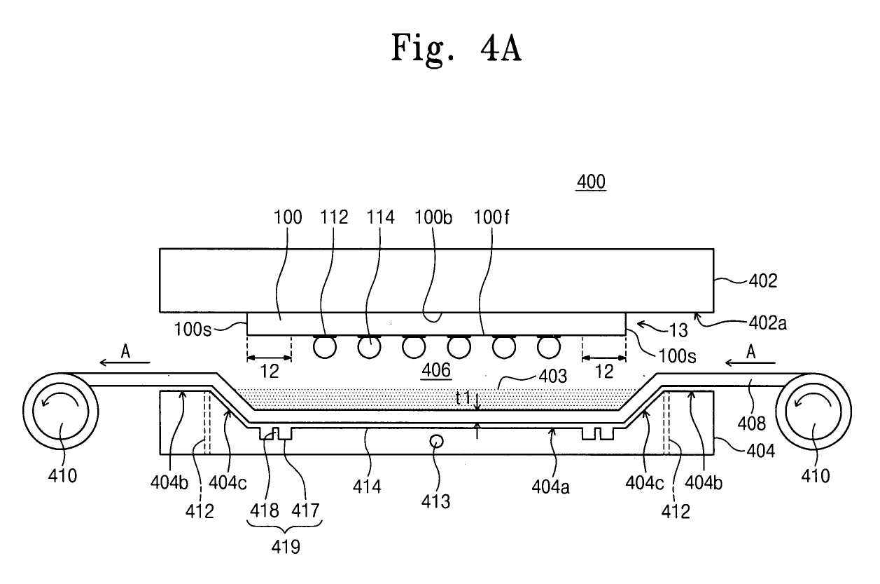

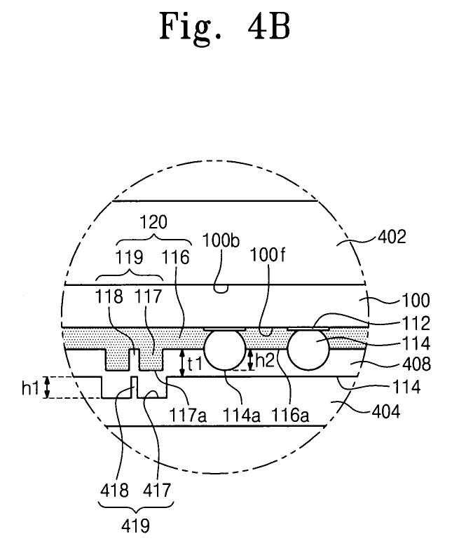

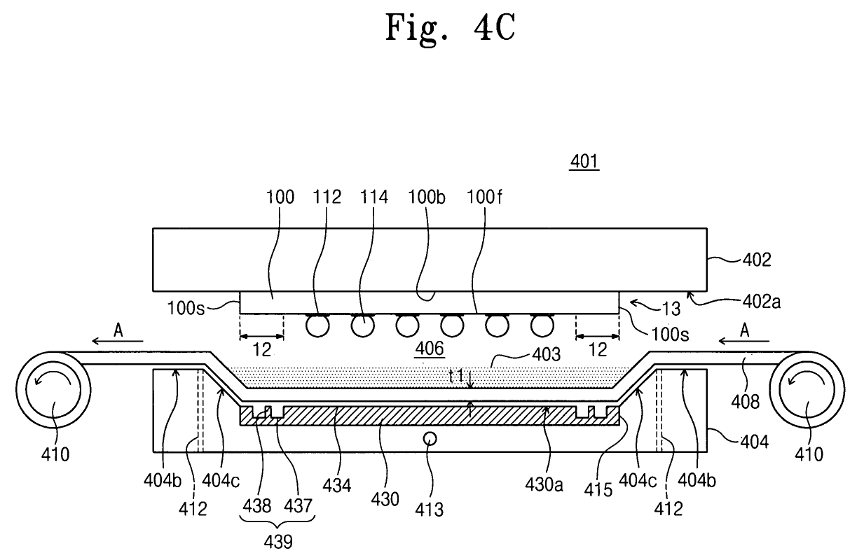

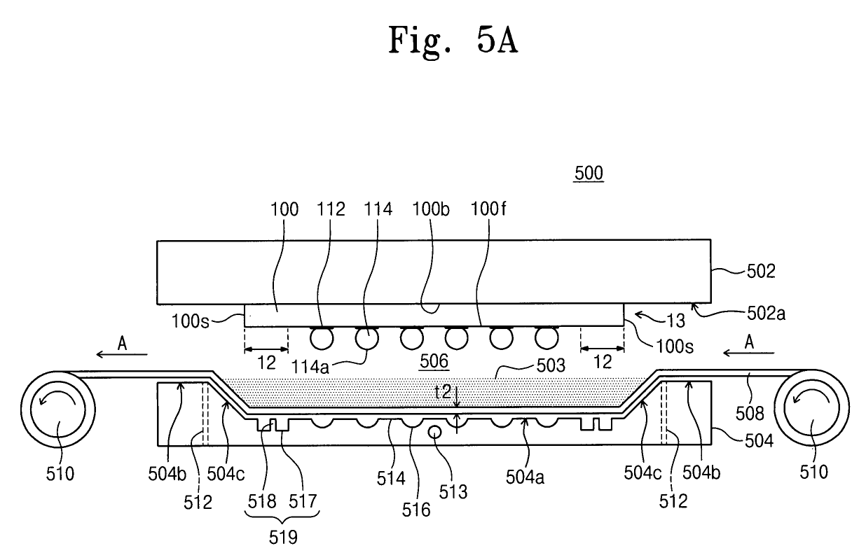

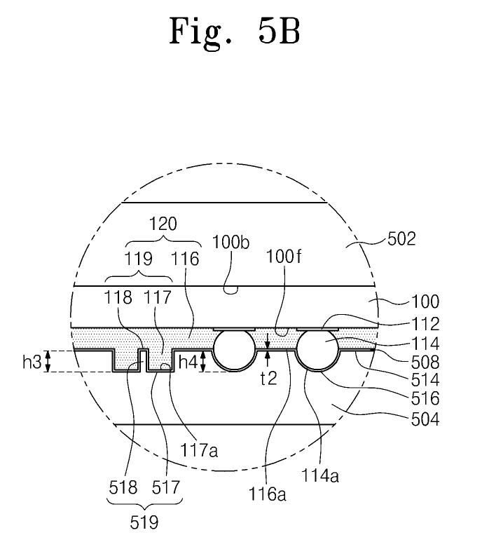

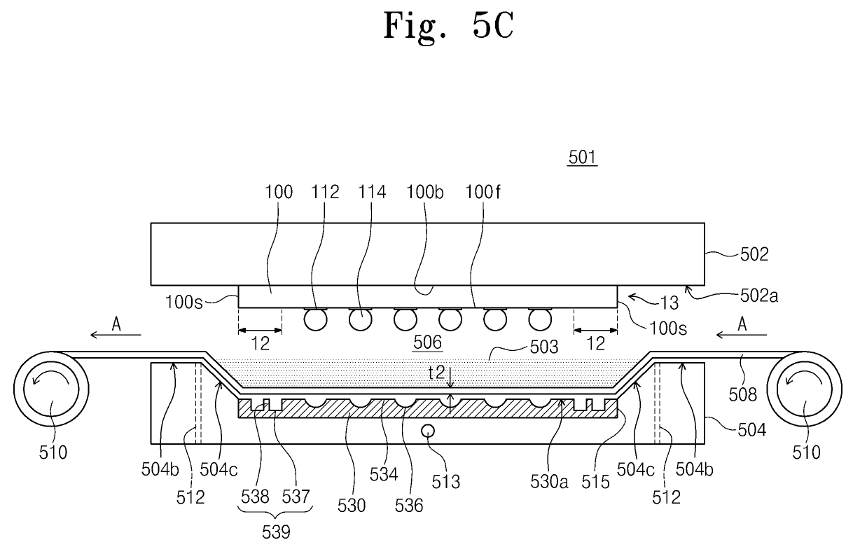

When forming the molding layer 120, an apparatus for manufacturing a semiconductor package that can simultaneously form the first molding layer 116 having the flat top surface 116a and the second molding layer 119 having a concave-convex shape may be used. The apparatus for manufacturing a semiconductor package will be described below referring to FIGS. 4A to 5C.

Referring to FIG. 1C, a dicing process (sawing process) dividing the substrate 100 along the dicing line d-d may be further performed. The substrate 100 may be divided into a plurality of chip unit substrates 101 and the molded wafer level package 15 may be divided into a plurality of chip unit semiconductor packages 16 by the dicing process. The dicing process may be performed using a blade cutter or a laser. The chip unit semiconductor package 16 may have a vertical side surface 101c at the outermost portion 101g of the substrate 101 by the dicing process. The groove 118 constituting the dicing line d-d is removed and the protrusion 117 having a vertical side surface 117c that is coplanar with the vertical side surface 101c of the substrate 101 remains on the active surface 110f of the outermost portion 101g

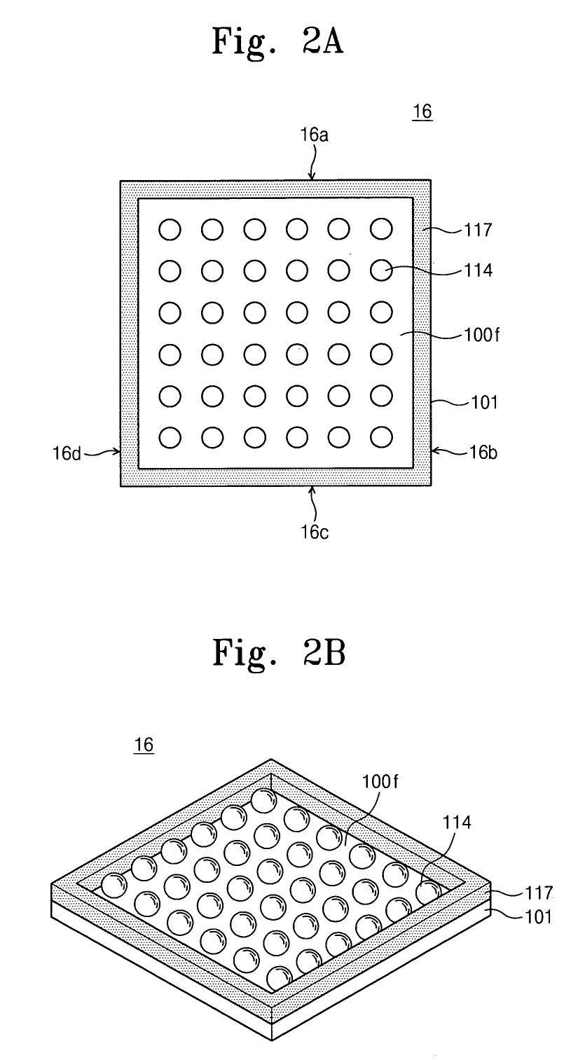

FIG. 2A is a top plan view of a semiconductor package embodied by a semiconductor manufacturing method in accordance with a first embodiment of the present invention and FIG. 2B is a perspective view of a semiconductor package embodied by a semiconductor manufacturing method in accordance with a first embodiment of the present invention.

Referring to FIGS. 2A and 2B, the protrusion 117 depicted in FIG. 1C is formed at an edge of the substrate 101 to make a wall shape surrounding an outer portion of the chip unit semiconductor package 16. For example, if the chip unit semiconductor package 16 has a square shape including four sides 16a through 16d, the protrusion 117 is disposed along the four sides 16a through 16d. Thus, the protrusion 117 has a wall shape surrounding the connection terminals 114 formed on the active surface 100f.

FIGS. 3A and 3B are cross-sectional views of a mount example of a semiconductor package embodied by a semiconductor manufacturing method in accordance with a first embodiment of the present invention.

Referring to FIG. 3A, the chip unit semiconductor package 16 can be mounted on an electrical module 36 such as a printed circuit board (PCB), the same or different kind of a semiconductor package, an electrical module 36, and the like. The electrical module 36 may include a substrate 30 on which an interconnection is formed. A pad 32 electrically connected to the connection terminal 114 may be formed on a top surface 30f of the substrate 30. A chip unit semiconductor package 16 can be mounted on the electrical module 36 so that an active surface 100f of the chip unit semiconductor package 16 faces a top surface 30f of the electrical module 36. The protrusion 117 may serve to support the chip unit semiconductor package 16, particularly an outer portion 101g of the substrate 101. The protrusion 117 may be not fixedly adhere to a top surface 30f of the substrate 30 through an adhesive but may simply adhere to the top surface 30f of the substrate 30.

When a stress 50 is applied to the chip unit semiconductor package 16, particularly the stress 50 is concentrated on the outer portion 101g of the substrate 101, breakage or bend of the substrate 101 can be suppressed or minimized because the protrusion 117 can absorb the stress 50 or disperse the stress 50 toward the substrate 30. A supporting role of the protrusion 117 may be useful in a case that a side surface 101c of the substrate 101 and the outermost connection terminal 114 have a comparatively great length.

Referring to FIG. 3B, if a height of the protrusion 117 is lower than a height of the connection terminal 114, a top surface 117a of the protrusion 117 may be spaced a predetermined distance g apart from the top surface 30f of the substrate 30. Thus, the protrusion 117 may be spaced apart from or simply in contact with the substrate 30 according to whether stresses 50 and 52 apply to the chip unit semiconductor package 16 and the electrical module 36 or not. The unsettled contact of the protrusion 117 and the substrate 30 makes the chip unit semiconductor package 16 to be mounted in a more flexible state as compared with the mounting described above with reference to FIG. 3A. For example, although the stress 52 is applied toward an external portion 30g of the substrate 30 to bend the substrate 30, the bending of the substrate 30 may not be transferred to the substrate 101 due to the predetermined distance g.

FIG. 4A is a cross-sectional view of an apparatus for manufacturing a semiconductor package in accordance with a first embodiment of the present invention.

Referring to FIG. 4A, an apparatus 400 for manufacturing a semiconductor package may be a mold die including an upper mold die 402 and a lower mold die 404. The upper mold die 402 may have a flat inner surface 402a. Unlike this, the lower mold die 404 may have a stepped inner surface including a first inner surface 404a, a second inner surface 404b and a third inner surface 404c. The first inner surface 404a may be disposed at a relatively low position. The second inner surface 404b may be disposed at a relatively high position. The third inner surface 404c may connect the first inner surface 404a and the second inner surface 404b. The third inner surface 404c may have an inclined shape or a vertical shape. The first to third inner surfaces 404a, 404b, and 404c may constitute a cavity 406 accommodating a molding material 403. The molding material may be a liquefied epoxy molding compound or a solid epoxy molding compound having a tablet type, powder type or sheet type. Either the upper mold die 402 or the lower mold die 404, or all of the upper and lower mold dies 402 and 404 may be designed to be heated so as to liquefy the molding material which is provided to the cavity 406 or transfer a heat to the molding material which is provided to the cavity 406.

The wafer level package 13 may be mounted on the upper mold die 402. For example, the wafer level package 13 may be mounted on the upper mold die 402 such that the active surface 100f of the substrate 100 may face the first inner surface 404a of the lower mold die 404 and the inactive surface 100b of the substrate 100 may face the inner surface 402a of the upper mold die 402. Mounting the wafer level package 13 on the upper mold die 402 may be performed by a vacuum absorption and/or a mechanical clamp.

The first inner surface 404a of the lower mold 404 may have a plane shape 414 and a concavo-convex shape 419. The concavo-convex surface 419 may be disposed on a position that is vertically aligned with the dicing region 12 of the substrate 100. The concavo-convex surface 419 may be formed to have two grooves 417 of a square shape and a protrusion 418 of a square shape protruded between the two grooves 417. A plurality of the dicing regions 12 may be disposed inside an edge of the substrate 100 and a plurality of the concavo-convex surface 419 may be disposed inside an edge of the first inner surface 404a.

A tape 408 may be disposed on the inner surfaces 404a, 404b and 404c. The tape 408 may be a kind of release tape so that the wafer level package 13 may be easily separated from the lower mold die 404 after a molding process. The tape 408 may be wound at a tape roller 410 disposed at both sides of the lower mold die 404. As the tape roller 410 rotates, the tape 408 moves in one direction A. As a result, the tape 408 may be input into and output from the inner surfaces 404a, 404b and 404c of the lower mold die 404. The lower mold die 404 may have a vacuum hole 412 that can absorb air. The vacuum hole 412 absorbs air, so that the tape 408 adheres to the inner surfaces 404a, 404b and 404c of the lower mold die 404. Since the tape 408, as will be described later, may participate in a formation of the molding layer 120, it may be preferable that tape 408 is consisted of a sufficiently flexible material that can be bent to have the same shape as the concavo-convex surface 419.

FIG. 4B is a cross-sectional view illustrating a method of molding a semiconductor package using an apparatus for manufacturing a semiconductor package in accordance with a first embodiment of the present invention. An apparatus for a semiconductor package in FIG. 4B depicts a portion of the apparatus.

Referring to FIG. 4B with FIG. 4A, the wafer level package 13 may be mounted on the upper mold die 402, the tape 408 may be provided to and absorbed on the inner surfaces 404a, 404b and 404c, and the molding material 403 may be provided to the cavity 406. As a result, the upper mold die 402 and the lower mold die 404 closely adhere to compress the molding material 403. In a case that the molding material 403 is compressed, the upper and lower mold dies 402 and 404 can apply heat to the molding material 403. If the molding material 403 is compressed, the molding material 403 applies a pressure to the tape 408 and at the same time, the connection terminal 114 pushes the tape 408 down. The tape 408 to which a pressure is applied may be bent to have the same shape as the concavo-convex surface 419 and at the same time, a portion of the top surface 114a of the connection terminal 114 may be recessed in the tape 408. It may be preferable that the tape 408 has a sufficient first thickness t1 that a portion of the top surface 114a of the connection terminal 114 can be recessed. The first thickness t1 may be equal to or greater than a depth h2 of the connection terminal 114 that is recessed in the tape 408.

Next, if the molding material 403 is hardened, the second molding layer 119 including the groove 118 and protrusions 117 formed by the protrusion 418 and the grooves 417 of the concavo-convex surface 419, respectively, may be formed and at the same time, the first molding layer 116 may be formed. The first molding layer 116 exposes a portion of the top surface 114a of the connection terminal 114 and has a flat top surface 116a. If the thickness t1 of the tape 408 and the depth h1 of the groove 417 are properly controlled, the top surface 117a of the protrusion 117 may have a height that is equal to or lower than the top surface 114a of the connection terminal 114 as described in FIG. 1B. In the first embodiment, the tape 408 may act as not only the release tape but also a kind of mold die forming a shape of a molding layer 120.

As shown in FIG. 1B, the first molding layer 116 including the flat top surface 116a parallel to the active surface of the substrate 100 and the second molding 119 of the concavo-convex shape may be simultaneously formed using the apparatus 400 for manufacturing a semiconductor package of the first embodiment. In a molding process, the molding layer 120 may be formed or not formed on the outermost surface 100s of the substrate 100 according to providing the molding material 403 to the outermost surface 100s of the substrate 100 or not.

The apparatus 400 may be what is called a compression mold die.

However, the apparatus 400 may not be limited to a compression mold die. The apparatus 400 may be a transfer mold die. In a case that the apparatus 400 is a transfer mold die, an injecting portion 413 giving a liquefied epoxy molding compound to the cavity 406 may be further provided.

FIG. 4C is a cross-sectional view of an apparatus for manufacturing a semiconductor package in accordance with a second embodiment of the present invention. Since an apparatus for manufacturing a semiconductor package of the second embodiment is similar to the apparatus for manufacturing a semiconductor package of the first embodiment, the description of common features already described in the first embodiment will not be repeated, while any new or different features will be described in further detail below.

Referring to FIG. 4C, an apparatus 401 for manufacturing a semiconductor package according to the second embodiment may be a mold die including an auxiliary mold die 430 that can be attached to and separated from the lower mold die 404. The lower mold die 404 includes an attaching portion 415 to which the auxiliary mold die 430 is fixedly attached. The attaching portion 415 may be designed to have a recessed shape so that the auxiliary mold die 430 is easily fixedly inserted. A top surface 430a of the auxiliary mold die 430 includes a plane 434 and a concavo-convex surface 439 and constitutes an inner surface of the lower mold die 404. The concavo-convex surface 439 may be disposed that is vertically aligned with the dicing region 12 of the substrate 100. The concavo-convex surface 419 may be formed to have two grooves 437 of a square shape and a protrusion 438 of a square shape protruded between the two grooves 437. A structure of the auxiliary mold die 430 may be changed according to a structure of a wafer level package 13. For example, if a location or a shape of the dicing region 12 changes, a location of a shape of the concavo-convex surface 439 may be properly changed according to this. The top surface 430a of the auxiliary mold die 430, and second and third inner surfaces 404b and 404c of the lower mold die 404 form a stepped shape, thus constituting the cavity 406 accommodating the molding material.

The apparatus 401 of the second embodiment can more flexibly meet with the structure of the wafer level package 13 as compared with the apparatus 400 of the first embodiment. This is because only the auxiliary mold die 430 can be replaced to correspond with the number and a location of the dicing region 12 of the wafer level package. Thus, the apparatus 401 of the second embodiment may be more useful than the apparatus 400 of the first embodiment.

FIG. 5A is a cross-sectional view of an apparatus for manufacturing a semiconductor package in accordance with a third embodiment of the present invention.

Referring to FIG. 5A, an apparatus 500 may be a mold die including an upper mold die 502 and a lower mold die 504. The wafer level package 13 may be mounted on the upper mold die 502 so that the active surface 100f of a substrate 100 may face the lower mold die 504. The wafer level package 13 may be mounted on the upper mold die 502 by means of a vacuum absorption and/or a mechanical clamp.

The upper mold die 502 may have a flat inner surface 520a. The lower mold die 504, on the other hand, may include a cavity 506 for accommodating a molding material 503. For example, the lower mold die 504 may include a first inner surface 504a that is disposed at a relatively low position, a second inner surface 504b that is disposed at a relatively high position and a third inner surface 504c that connects the first and second inner surfaces 504a and 504b. The third surface 504c may have an inclined shape or a vertical shape. The molding material 503 may be a liquefied epoxy molding compound or a solid epoxy molding compound having a tablet type, powder type or sheet type. The upper mold die 502 and/or the lower mold die 504 may be designed to be heated so as to liquefy the molding material 503 which is provided to the cavity 506 or transfer a heat to the molding material 503 which is provided to the cavity 506.

The first inner surface 504a of the lower mold 504 may have a plane shape 514, a concavo-convex shape 519 and a dent 516. The concavo-convex surface 519 may be disposed on a position that is vertically aligned with the dicing region 12 of the substrate 100. The dent 516 may be disposed on a location that is aligned with the connection terminal 114. The concavo-convex surface 519 may be formed to have two grooves 517 of a square shape and a protrusion 518 of a square shape protruded between the two grooves 517. A location and the number of the concavo-convex surface 519 may coincide with a location and the number of the dicing region 12. The dent 516 may have a shape that a portion of the top surface 114a of the connection terminal 114 can be inserted. For example, if the connection terminal 114 is a sphere shape, the dent 516 may be a bowl shape of a hemisphere. A location and the number of the dent 516 may coincide with a location and the number of the connection terminal 114.

A tape 508 may be disposed on the inner surfaces 504a, 504b and 504c of the lower mold die 504. The tape 508 may be formed of sufficiently flexible material that can be bent along the concavo-convex surface 519 and the dent 516. The tape 508 may be wound at a tape roller 510 disposed at both sides of the lower mold die 504. As the tape roller 510 rotates, the tape 508 moves in one direction A. As a result, the tape 508 may be input into and output from the inner surfaces 504a, 504b and 504c of the lower mold die 504. The lower mold die 504 may have a vacuum hole 512 that can absorb the tape 508. Like the tape 408 of the first embodiment, the tape 508 of the third embodiment may have a sufficient first thickness t1 that a portion of the connection terminal 114 can be recessed. Differently, the tape 508 may serve as a kind of release tape so that the wafer level package 13 may be easily separated from the lower mold die 404 after a molding process. Thus, it may be not necessary that the connection terminal 114 is recessed in the tape 508. The tape 508 may have a second thickness t2 that is less than the first thickness t1 described in FIG. 4A.

FIG. 5B is a cross-sectional view illustrating a method of molding a semiconductor package using an apparatus for manufacturing a semiconductor package in accordance with a third embodiment of the present invention.

Referring to FIG. 5B with FIG. 5A, the wafer level package 13 may be mounted on the upper mold die 502, and the tape 508 may be provided and absorbed on the inner surfaces 504a, 504b and 504c of the lower mold die 504. If the molding material 503 is provided to the cavity 506, the upper and lower mold dies 502 and 504 adhere to each other to compress the molding material 503. In a case that the molding material 503 is compressed, heat may be applied to the molding material 503.

If the molding material 503 is compressed, the molding material 503 has a concavo-convex shape and a flat shape along the concavo-convex surface 519 and the plane 514 and at the same time, the portion of the top surface 114a of the connection terminal 114 is inserted into the dent 516. If the molding material 503 is hardened, the second molding layer 119 including a groove 118 and protrusions 117 formed by the protrusion 518 and the groove 517 of the concavo-convex surface 419, respectively may be formed and at the same time, the first molding layer 116 may be formed. The first molding layer 116 may expose a portion of the top surface 114a of the connection terminal 114 and may have a flat top surface 116a. If a depth h3 of the groove 517 is set up to be equal to or less than a depth h4 of the dent 516, the top surface 117a of the protrusion 117 may have a height that is equal to or lower than the top surface 114a of the connection terminal 114 as described in FIG. 1B. If the second thickness t2 of the tape 508 is equal to or greater than the depth h4 of the dent 516, a portion of the connection terminal 114 can not be recessed. Thus, the second thickness t2 of the tape 508 should be sufficiently smaller as compared with the depth h4 of the dent 516.

As shown in FIG. 1B, the first molding layer 116 having the flat top surface 116a and the second molding layer 119 having the concavo-convex shape can be simultaneously formed on the active region 100f of the substrate 100 by using the apparatus 500 according to the third embodiment The molding layer 120 may be formed or may not be formed on the outermost side surface of the substrate 100.

The apparatus 500 may be what is called a compression mold die. However, the apparatus 500 may not be limited to a compression mold die and may be a transfer mold die. In a case that the apparatus 500 is a transfer mold die, an injection portion 513 giving a liquefied epoxy molding compound to the cavity 506 may be further provided.

FIG. 5C is a cross-sectional view of an apparatus for manufacturing a semiconductor package in accordance with a fourth embodiment of the present invention.

Referring to FIG. 5C, an apparatus 501 according to the fourth embodiment may be a mold die including an auxiliary mold die 530 that can be attached to and separated from a lower mold die 504 and may have a top surface 530a including a plane 534, a concavo-convex surface 539 and a dent 536. The lower mold die 504 may include an attaching portion 515 of a recessed shape to which the auxiliary mold die 530 is fixedly attached. The concavo-convex surface 539 may be disposed at a region that is vertically aligned with the dicing region 12 and the dent 536 may be disposed at a region that is vertically aligned with the connection terminal 114. The concavo-convex surface 539 may be formed to have two grooves 537 of a square shape and a protrusion 538 of a square shape protruded between the two grooves 537. A location and the number of the concavo-convex surface 539 may coincide with a location and the number of the dicing region 12. The dent 536 may have a shape that a portion of the top surface 114a of the connection terminal 114 can be inserted into the auxiliary mold die 530. For example, if the connection terminal 114 is a sphere shape, the groove surface 536 may be a bowl shape of a hemisphere. A location and the number of the groove surface 536 may coincide with a location and the number of the connection terminal 114. The top surface 530a of the auxiliary mold die 530, and second and third inner surfaces 504b and 504c of the lower mold die 504 forming a stepped shape constitute a cavity 506 accommodating a molding material.

In the apparatus 501 of the fourth embodiment, the concavo-convex surface 539 and the groove surface 536 may be formed on the auxiliary mold die 530 that can be attached to and separated from the lower mold die 504. Thus, if a location and the number of the dicing region 12 and the connection terminal 114 are altered, only the auxiliary mold die 530 can be replaced. Except the elements described above, a description of remaining elements is the same as the description of the apparatus 500 of the third embodiment.

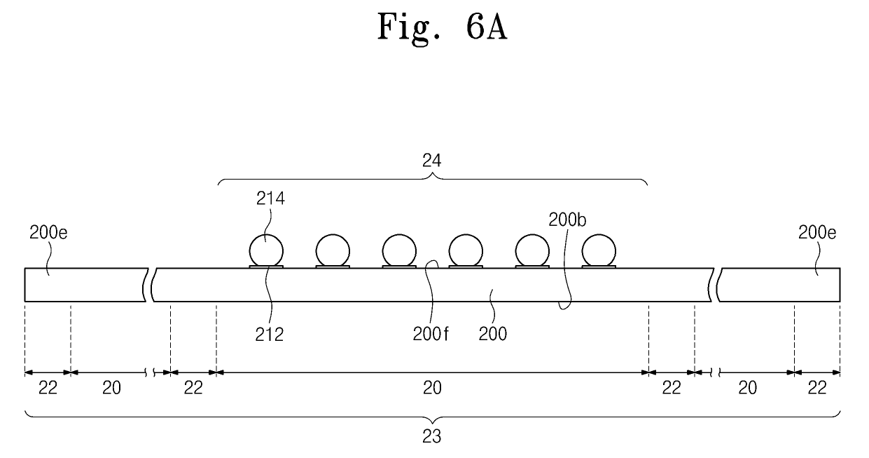

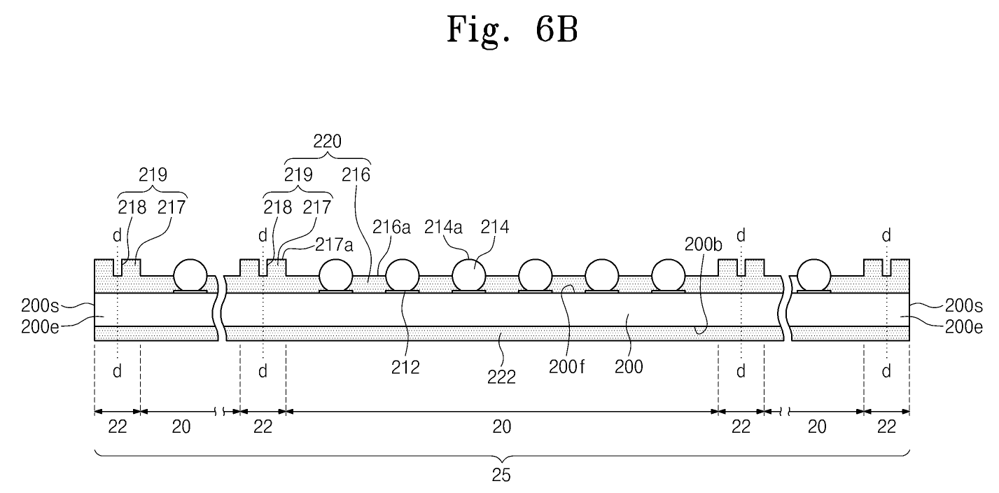

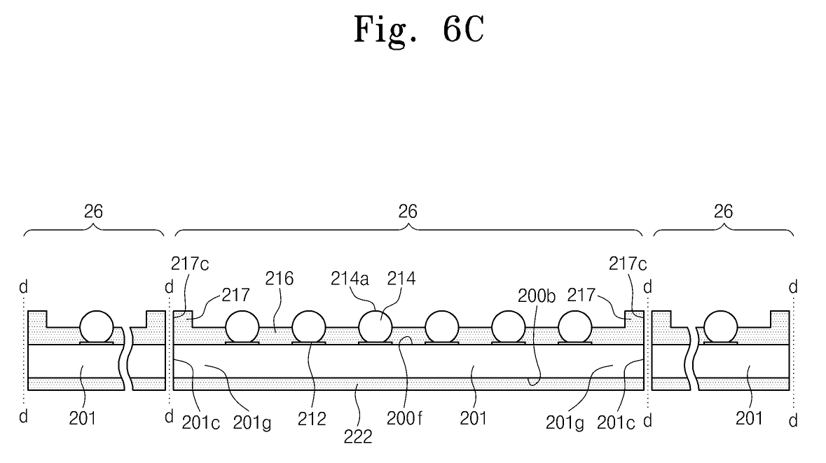

FIGS. 6A to 6C are cross-sectional views illustrating a method of manufacturing a semiconductor package in accordance with a second embodiment of the present invention. Since the method of manufacturing a semiconductor package according to the second embodiment is similar to the method of manufacturing a semiconductor package of the first embodiment, the description of common features already described in the first embodiment will be omitted for brevity, while any new or different features will be described in further detail below.

Referring to FIG. 6A, a substrate 200 of a wafer unit such as a silicon wafer is provided. A plurality of pads 212 may be formed on an active surface 200f of the substrate 200 and a plurality of connection terminals 214 electrically connected to the pads 212 may be formed on the pads 212. As a result, a wafer level package 23 may be accomplished. The substrate 200 may be divided into a chip region 20 and a dicing region 22. The dicing region 22 may not be present in an outermost region of the substrate 200. If the substrate 200 is cut along the dicing region 22, a plurality of chip unit semiconductor packages 24 may be accomplished. A molding process may be further performed so as to prevent a damage or breakage such as chipping.

Referring to FIG. 6B, an upper molding layer 220 may be formed on the active surface 200f of the substrate 200 and a lower molding layer 222 may be formed on an inactive surface 200b. A molded wafer level package 25 that the active surface 200f and the inactive surface 200b of the substrate 200 are all protected by the upper and lower molding layers 220 and 222 may be accomplished. The upper and lower molding layers 220 and 222 can be simultaneously formed by using an epoxy molding compound. The upper molding layer 220 may be divided into a first molding layer 216 disposed on the active surface 200f that belongs to the chip region 20 and a second molding layer 219 disposed on the active surface 200f that belongs to the dicing region 22. The first molding layer 216 may be formed to have a flat top surface 216a. The second molding layer 219 may be formed to have a concavo-convex shape that serves as a mark to easily recognize the dicing region 22. The upper molding layer 220 or the lower molding layer 222 may be formed or not be formed to extend to the outermost side 200s of the substrate 200.

The second molding layer 219 may be formed to have two protrusions 217 of square shape and a groove 218 of a square shape recessed between the two protrusions 217. The groove 218 may serve as a dicing line d-d. A height of the protrusion 217 may be arbitrary. For example, a top surface 217a of the protrusion 217 may be even with or lower than the top surface 214a of the connection terminal 214. The second molding layer 219 may include the protrusions 217 and the groove 218, or may include one protrusion 217. When the molded wafer level package 25 is mounted on an electrical module, the second molding layer 219 may serve as a supporter as described in FIG. 1B.

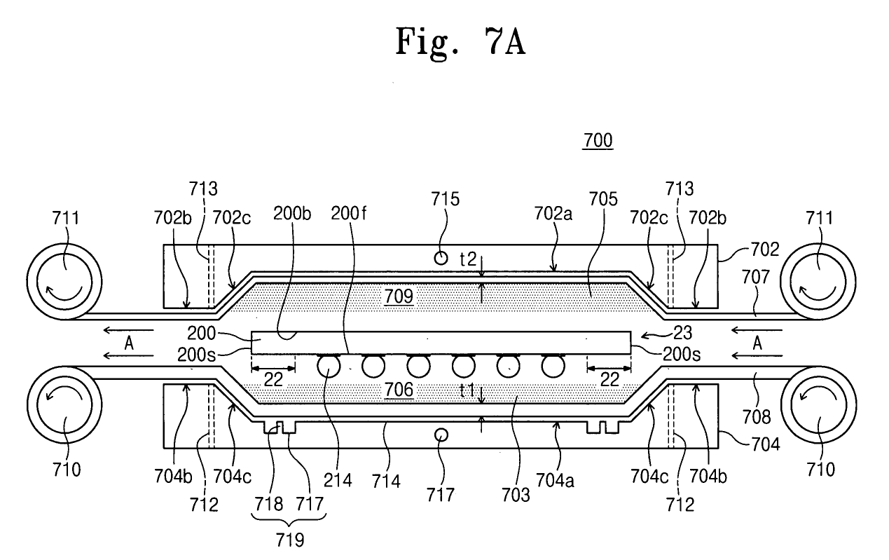

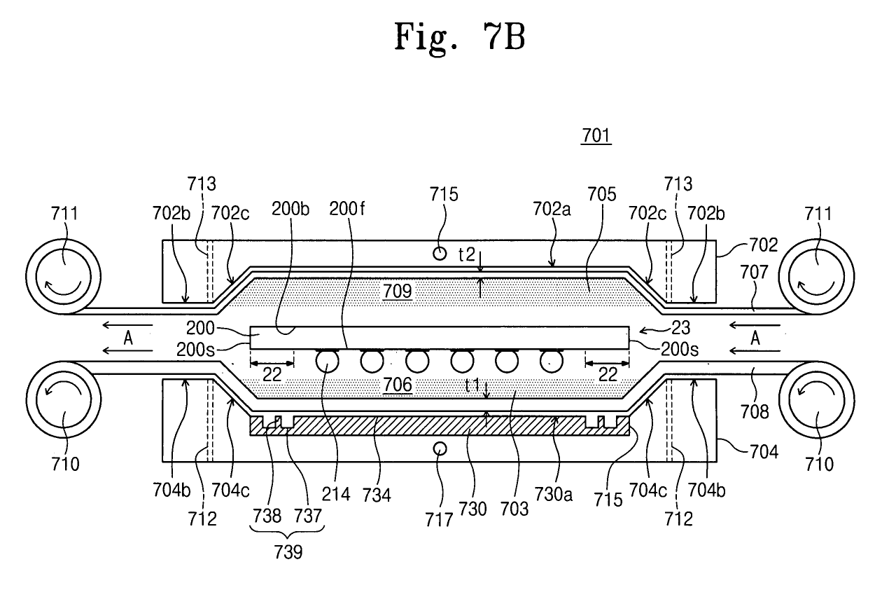

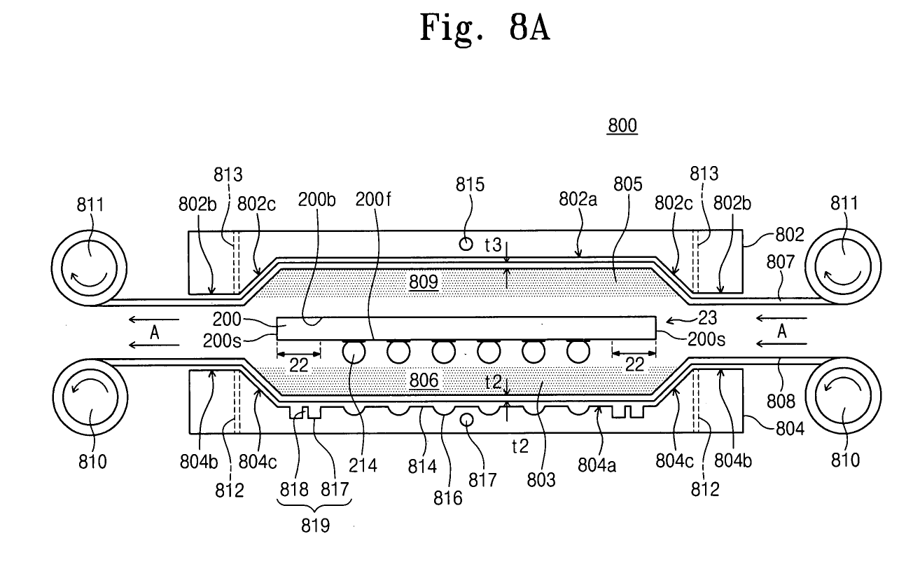

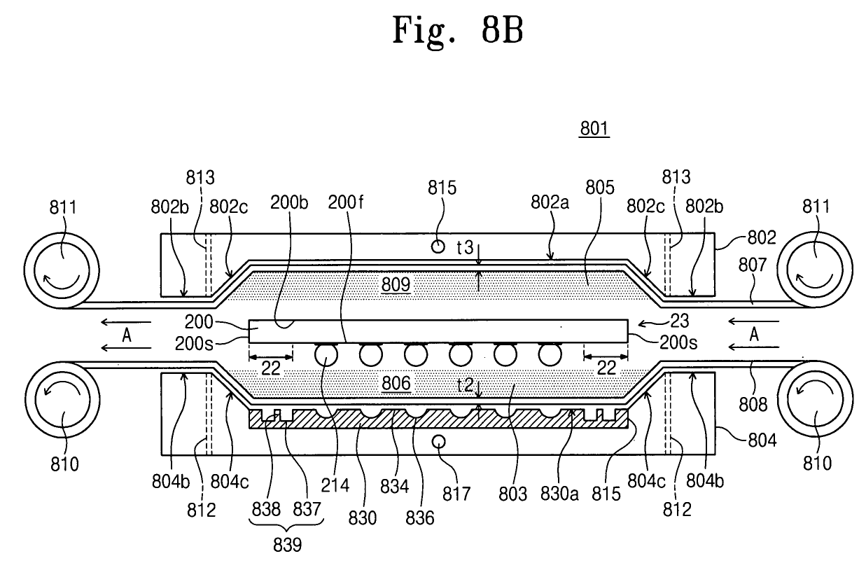

In a molding process, the upper and lower molding layers 220 and 222 can be simultaneously formed, and the first molding layer 216 and the second molding layer 219 can also be simultaneously formed. The molding process may proceed using an apparatus for manufacturing a semiconductor package that will be described later with reference to FIGS. 7A to 8B.

Referring to FIG. 6C, a dicing process (sawing process) dividing the substrate 200 along the dicing line d-d may be further performed. According to the dicing process, a chip unit semiconductor package 26 may be accomplished. The active surface 200f of the chip unit semiconductor package 26 may be molded by the first molding layer 216 and the protrusion 217, and the inactive surface 200b of the chip unit semiconductor package 26 may be molded by the lower molding layer 222. The protrusion 217, as described in FIGS. 2A and 2B, may be formed on the outside of the chip unit semiconductor package 26 and formed to have a barrier shape surrounding the connection terminals 214. The protrusion 217, as described in FIGS. 3A and 3B, may serve as a supporter and may increase a mechanical reliability or endurance of the chip unit semiconductor package 26.

FIG. 7A is a cross-sectional view of an apparatus for manufacturing a semiconductor package in accordance with a fifth embodiment of the present invention.

Referring to FIG. 7A, an apparatus 700 for manufacturing a semiconductor package may be a mold die including an upper mold die 702 and a lower mold die 704. The wafer level package 23 may be mounted between the upper mold die 702 and the lower mold die 704. More specifically, the wafer level package 23 may be disposed so that the active surface 200f of the substrate 200 may face the lower mold die 704 and the inactive surface 200b may face the upper mold die 702.

The lower mold die 704 may include a first inner surface 704a that may be disposed at a relatively low position, a second inner surface 704b that may be disposed at a relatively high position and a third inner surface 704c that may connect the first and second inner surfaces 704a and 704b. The third surface 704c may have an inclined shape or a vertical shape. The first through third inner surfaces 704a-704c may constitute a stepped shape to constitute a lower cavity 706 accommodating a first molding material 703. A lower injecting portion 717 may be provided at the lower mold die 704 to inject the first molding material 703 to the lower cavity 706.

The first inner surface 704a of the lower mold die 704 may comprise a plane 714 and a concavo-convex surface 719. The concavo-convex surface 719 may be disposed at a location that is vertically aligned with a dicing region 22. The concavo-convex surface 719 may comprise two grooves 717 of a square shape and a protrusion 718 of a square shape protruded between the two grooves 717. The dicing region 22 may be disposed at both edges of the substrate 200 but it is not limited to this and may be disposed at a plurality of any locations.

A lower tape 708 may be provided on the first through third inner surfaces 704a-704c of the lower mold die 704. The lower tape 708 may be wound at a lower tape roller 710 disposed at both sides of the lower mold die 704. As the lower tape roller 710 rotates, the lower tape 708 moves in one direction A. As a result, the lower tape 708 may be input into and output from the inner surfaces 704a, 704b and 704c of the lower mold die 704. The lower mold die 704 may have a vacuum hole 712 that can absorb air. The vacuum hole 712 absorbs air, so that the tape 708 adheres to the inner surfaces 704a, 704b and 704c of the lower mold die 704.

The lower tape 708 may be consisted of sufficiently flexible material that can be bent to have the same shape as the concavo-convex surface 719. The tape 708 may have the first thickness t1 that a portion of the connection terminal 214 can be recessed, which may result that the first molding layer 216 is formed to cover a portion of the connection terminal 214. The lower tape 708 may serve as a kind of mold die that embodies the shape of the upper molding layer (220 of FIG. 6B) and serve as a release tape that easily separates the wafer level package 23 from the lower mold die 704 after a molding process.

The upper mold die 702 may include a first inner surface 702a that is disposed at a relatively high position, a second inner surface 702b that is disposed at a relatively low position and a third inner surface 702c that connects the first and second inner surfaces 702a and 702b. The third surface 702c may have an inclined shape or a vertical shape. Stepped first to third inner surfaces 702a, 702b and 702c may constitute an upper cavity 709 accommodating a second molding material 705. An upper injecting portion 715 may be provided at the upper mold die 702 to inject the second molding material 705 to the upper cavity 709.

An upper tape 707 may be provided on the inner surfaces 702a, 702b and 702c of the upper mold die 702. The upper tape 707 may be wound at an upper tape roller 711 disposed at both sides of the upper mold die 702. As the upper tape roller 711 rotates, the upper tape 707 may move in one direction A. As a result, the upper tape 707 may be input into and output from the inner surfaces 702a, 702b and 702c of the upper mold die 702. The upper mold die 702 may have an upper vacuum hole 713. The upper vacuum hole 713 absorbs air, so that the upper tape 707 adheres to the inner surfaces 702a-702c of the upper mold die 702.

The upper tape 707 may be a kind of release tape that can easily separate the wafer level package 23 from the upper mold die 704 after the molding process is performed. Thus, the upper tape 707 may have a thickness that is equal to or similar to the first thickness t1 of the lower tape 708, or the upper tape 707 may have a second thickness t2 that is smaller than the first thickness t1.

The first molding material 703 may be a liquefied epoxy molding compound. The second molding material 705 may be equal to the first molding material 703. However, the first and second molding materials 703 and 705 are not limited to a liquefied material, and may be a solid material such as an epoxy molding compound having a tablet type, powder type or sheet type. The upper mold die 702 and/or the lower mold die 704 may be designed to be heated so as to liquefy the first and second molding material 703 and 705 or transfer a heat to the first and second molding material 703 and 705.

A molding process using the apparatus 700 of the fifth embodiment may be as follows.

Referring back to FIG. 7A, the wafer level package 23 may be mounted on the upper mold die 702. Before or after the wafer level package 23 may be mounted on the upper mold die 702, the upper tape 707 may adhere to the inner surfaces 702a-702c of the upper mold die 702 and the lower tape 708 may adhere to the inner surfaces 704a-704c of the lower mold die 704. Subsequently, the upper mold die 702 may closely adhere to the lower mold die 704, and then the first molding material 703 may be provided to the lower cavity 706 through the lower injecting portion 717 and the second molding material 705 may be provided to the upper cavity 709 through the upper injecting portion 715.

If the first and second molding materials 703 and 705 are hardened, as shown in FIG. 6B, the upper molding layer 220 including the first molding layer 216 having the flat top surface 216a and the second molding layer 219 having the concavo-convex shape may be formed on the active surface 200f of the substrate 200. At the same time, the lower molding layer 222 may be formed on the inactive surface 200b. The first molding material 703 may be or may not be provided to the outermost side surface 200s of the substrate 200. Accordingly, the upper molding layer 220 may be formed to extend to the outermost side surface 200s or not be formed on the outermost side surface 200s. Similarly, the second molding material 705 may be or may not be provided to the outermost side surface 200s of the substrate 200. Accordingly, the lower molding layer 222 may be formed to extend to the outermost side surface 200s of the substrate 200 or not be formed on the outermost side surface 200s of the substrate 200.

The apparatus 700 described above may be what is called a transfer mold die. Differently, the apparatus 700 may be a transfer mold die so as to form the upper molding layer 220 and the lower molding layer 222 on the active surface 200f and the inactive surface 200b of the substrate 200, respectively. However, the apparatus 700 may not be limited to a transfer mold die and may be a compression mold die. In a case that the apparatus 700 may be a compression mold die, it may be preferable to adopt an epoxy molding compound of a sheet type so as to simultaneously form the upper molding layer 220 and the lower molding layer 222.

FIG. 7B is a cross-sectional view of an apparatus for manufacturing a semiconductor package in accordance with a sixth embodiment of the present invention. Since an apparatus for manufacturing a semiconductor package of the sixth embodiment is similar to the apparatus for manufacturing a semiconductor package of the fifth embodiment, the description of common features already described in the fifth embodiment will be omitted for brevity, while any new or different features will be described in further detail below.

Referring to FIG. 7B, the apparatus 701 for manufacturing a semiconductor package of the sixth embodiment may be a mold die including an auxiliary mold die 730 that can be attached to and separated from the lower mold die 704. The lower mold die 704 may include an attaching portion 715 to which the auxiliary mold die 730 is fixedly attached. The attaching portion 715 may be designed to have a recessed shape so that the auxiliary mold die 730 can be easily fixedly inserted. A top surface 730a of the auxiliary mold die 730 may have a plane 734 and a concavo-convex surface 739. The concavo-convex surface 739 may be disposed at a location that is vertically aligned with the dicing region 22 of the substrate 200. The concavo-convex surface 719 may be formed to have two grooves 737 of a square shape and a protrusion 738 of a square shape protruded between the two grooves 737. A location and the number of the concavo-convex surface 739 may coincide with a location and the number of the dicing region 22. The top surface 730a of the auxiliary mold die 730, and the second and third inner surfaces 704b and 704c may form a stepped shape, so that the lower cavity 706 to accommodate the first molding material 703 may be formed.

The apparatus 701 of the sixth embodiment can more flexibly meet with a structure of the wafer level package 23 as compared with the apparatus 700 of the fifth embodiment. This is because only the auxiliary mold die 730 can be replaced. Thus, the apparatus 701 of the sixth embodiment may be more useful than the apparatus 700 of the fifth embodiment.

FIG. 8A is a cross-sectional view of an apparatus for manufacturing a semiconductor package in accordance with a seventh embodiment of the present invention.

Referring to FIG. 8A, an apparatus 80 for manufacturing a semiconductor package in accordance with a seventh embodiment may be a mold die including an upper mold die 802 and a lower mold die 804. The wafer level package 23 may be mounted between the upper mold die 802 and the lower mold die 804. The wafer level package 23 may be mounted so that the active surface 200f may face the lower mold die 704.

The lower mold die 804 may be formed so that a lower cavity 806 to which a first molding material 803 is provided may be formed. The lower mold die 804 may include a first inner surface 804a that is disposed at a relatively low position, a second inner surface 804b that is disposed at a relatively high position and a third inner surface 804c that connects the first and second inner surfaces 804a and 804b. The third surface 804c may have an inclined shape or a vertical shape. A lower injecting portion 817 for providing a first molding material 803 may be formed in the lower mold die 804.

Similarly, the upper mold die 802 may be formed so that an upper cavity 809 to which a second molding material 805 is provided may be formed. The upper mold die 802 may include a first inner surface 802a that is disposed at a relatively high position, a second inner surface 802b that is disposed at a relatively low position and a third inner surface 802c that connects the first and second inner surfaces 802a and 802b. The third surface 802c may have an inclined shape or a vertical shape. An upper injecting portion 815 for providing a second molding material 805 may be formed in the upper mold die 802.

The first and second molding materials 803 and 805 may be the same material, e.g., a liquefied epoxy molding compound or an epoxy molding compound having a tablet type, powder type or sheet type. The lower mold die 804 may be designed to be heated so as to liquefy the first molding material 803 which is provided to the lower cavity 806 or transfer a heat to the first molding material 803 which is provided to the lower cavity 806. Similarly, the upper mold die 802 may be designed to be heated so as to liquefy the second molding material 805 which is provided to the upper cavity 809 or transfer a heat to the second molding material 805 which is provided to the upper cavity 809.

The first inner surface 802a of the upper mold 802 may be flat and the first inner surface 804a of the lower mold die 804 may be a plane shape 814, a concavo-convex shape 819 and a dent 816. The concavo-convex surface 819 may be vertically aligned with a dicing region 22 and the dent 816 may be vertically aligned with a connection terminal 214. The concavo-convex surface 819 may be formed to have two grooves 817 of a square shape and a protrusion 818 of a square shape. A location and the number of the concavo-convex surface 819 may coincide with a location and the number of the dicing region 22. The groove surface 816 may have a shape that a portion of a top surface 214a of the connection terminal 214 can be inserted. For example, if the connection terminal 214 is a sphere shape, the dent 816 may be a bowl shape of a hemisphere. A location and the number of the groove surface 816 may coincide with a location and the number of the connection terminal 214.

A lower tape 808 may be provided on the inner surfaces 804a, 804b and 804c of the lower mold die 804. The lower tape 808 may be formed of sufficiently flexible material that can be bent along the concavo-convex surface 819 and the dent 816. The lower tape 808 may be wound at a lower tape roller 810 disposed at both sides of the lower mold die 804. As the lower tape roller 810 rotates, the lower tape 808 may move in one direction A, so that the lower tape 808 may be input into and output from the inner surfaces 804a-804c of the lower mold die 804. The lower mold die 804 may have a vacuum hole 812 that can absorb the lower tape 808. The lower tape 808 may be a kind of release tape that can easily separate the wafer level package 23 from the lower mold die 804 after a molding process is performed. Thus, the lower tape 808 of the seventh embodiment may have the thickness t1 that is comparatively thick like the lower tape 708 of the fifth embodiment and preferably may have a second thickness t2 that is much smaller than the first thickness t1.

Similarly, an upper tape 807 may be disposed on the inner surfaces 802a, 802b and 802c of the upper mold die 802. The upper tape 807 may be wound at an upper tape roller 811 disposed at both sides of the upper mold die 802. As the upper tape roller 811 rotates, the upper tape 807 may move in one direction A, so that the upper tape 807 may be input into and output from the inner surfaces 802a, 802b and 802c of the upper mold die 802. The upper mold die 802 may have a vacuum hole 813 that can absorb the upper tape 807. The upper tape 807 may be a kind of release tape that can easily separate the wafer level package 23 from the upper mold die 802 after a molding process is performed. Thus, the upper tape 807 of the seventh embodiment may have a thickness that is equal to or similar to the first thickness t1 like the lower tape 708 of the fifth embodiment and may have a third thickness t3 that is much smaller than the first thickness t1. The thickness t3 of the upper tape 807 may be equal to the thickness t2 of the lower tape 808.

A molding process using the apparatus 800 of the seventh embodiment may be as follows.

Referring again to FIG. 8A, the wafer level package 23 may be mounted on the upper mold die 702. Before or after the wafer level package 23 may be mounted on the upper mold die 702, the upper tape 707 may adhere to the inner surfaces 702a, 702b and 702c of the upper mold die 702 and the lower tape 708 may adhere to the inner surfaces 704a, 704b and 704c of the lower mold die 704. Subsequently, the upper mold die 702 and the lower mold die 704 may adhere closely, and the first molding material 703 may be provided to the lower cavity 706 through the lower injecting portion 717 and the second molding material 705 may be provided to the upper cavity 709 through the upper injecting portion 715.

If the first and second molding materials 703 and 705 are hardened, as shown in FIG. 6B, an upper molding layer 220 including the first molding layer 216 having the flat top surface 216a and the second molding layer 219 having the concavo-convex shape may be formed on the active surface 200f of the substrate 200. At the same time, the lower molding layer 222 may be formed on the inactive surface 200b. The first molding material 703 may be or may not be provided to the outermost side surface 200s of the substrate 200. Accordingly, the upper molding layer 220 may be formed to extend to the outermost side surface 200s or not be formed on the outermost side surface 200s. Similarly, the second molding material 705 may be or may not be provided to the outermost side surface 200s of the substrate 200. Accordingly, the lower molding layer 222 may be formed to extend to the outermost side surface 200s of the substrate 200 or not be formed on the outermost side surface 200s of the substrate 200.

The apparatus 700 may be a transfer mold die. However, the apparatus 700 may not be limited to a transfer mold die and may be a compression mold die. In a case that the apparatus 700 may be a compression mold die, it may be preferable to adopt an epoxy molding compound of a sheet type so as to simultaneously form the upper molding layer 220 and the lower molding layer 222.

FIG. 8B is a cross-sectional view of an apparatus for manufacturing a semiconductor package in accordance with an eighth embodiment of the present invention. Since an apparatus for manufacturing a semiconductor package of the eighth embodiment is similar to the apparatus for manufacturing a semiconductor package of the seventh embodiment, the description of common features already described in the fifth embodiment will be omitted for brevity, while any new or different features will be described in further detail below.

Referring to FIG. 8B, an apparatus 801 for manufacturing a semiconductor package of the eighth embodiment may be a mold die including an auxiliary mold die 830 that can be attached to and separated from the lower mold die 804 and has a top surface 830a including a plane 834, a concavo-convex surface 839 and a dent 836. The lower mold die 804 may include an attaching portion 815 of a recessed shape to which the auxiliary mold die 830 is fixedly attached. The concavo-convex surface 839 may be disposed at a location that is vertically aligned with the dicing region 22 of the substrate 200 and the dent 836 may be disposed at a location that is vertically aligned with the connection terminal 214. The concavo-convex surface 819 may be formed to have two grooves 837 of a square shape and a protrusion 838 of a square shape protruded between the two grooves 837. A location and the number of the concavo-convex surface 839 may coincide with a location and the number of the dicing region 22. The dent 836 may have a shape that a portion of a top surface 214a of the connection terminal 214 can be inserted. For example, if the connection terminal 214 is a sphere shape, the dent 816 may be a bowl shape of a hemisphere. A location and the number of the dent 836 may coincide with a location and the number of the connection terminal 214. The top surface 830a of the auxiliary mold die 830, and the second and third inner surfaces 804b and 804c may form a stepped shape, so that a lower cavity 806 accommodating the first molding material 806 may be formed.

The apparatus 801 of the eighth embodiment can more flexibly meet with a structure of the wafer level package 23 as compared with the apparatus 800 of the seventh embodiment.

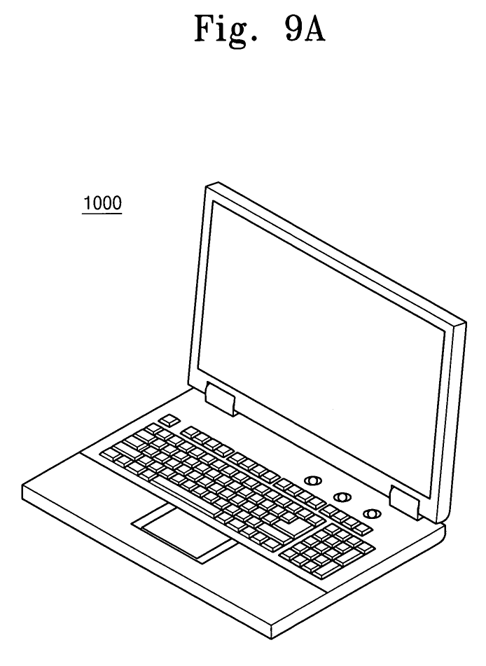

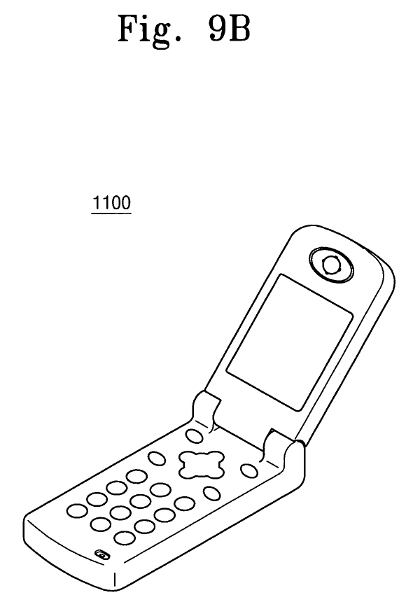

FIGS. 9A and 9B are perspective views of an electronic device equipped with a semiconductor package in accordance with example embodiments of the present invention.

Referring to FIGS. 9A and 9B, a semiconductor package according to the embodiments of the present invention may be used in an electronic device such as a note book 1000 or a cell phone 1100. The electronic device may also include a variety of display apparatus such as a desk top computer, a camcorder, a MP3, a liquid crystal display (LCD) or a plasma display panel (PDP).

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A wafer level semiconductor package comprising:
a substrate having an active surface and an inactive surface opposed to the active surface, and comprising a chip region and a dicing region;
a connection terminal disposed on the active surface of the chip region;
a first molding layer covering the active surface of the chip region and exposing a portion of the connection terminal; and
a second molding layer covering the active region of the dicing region and having a different surface shape from the first molding layer so as to recognize a dicing line dividing the chip regions.

2. The wafer level semiconductor package of claim 1, wherein the first molding layer includes a first top surface having a flat shape and the second molding layer includes a second top surface having an irregular shape.

3. The wafer level semiconductor package of claim 1, wherein the second top surface is higher than the first top surface.

4. The wafer level semiconductor package of claim 3, wherein the second top surface is as high as or lower than a top surface of the connection terminal.

5. The wafer level semiconductor package of claim 4, wherein the first top surface is lower than the top surface of the connection terminal.

6. The wafer level semiconductor package of claim 2, wherein the second molding layer includes protrusions higher than the first top surface and a groove disposed between the protrusions.

7. The wafer level semiconductor package of claim 6, wherein the groove constitutes the dicing line.

8. The wafer level semiconductor package of claim 1, further comprising a third molding layer covering the inactive surface.

9. A chip level semiconductor package, comprising:
a substrate including an active surface and an inactive surface;
a connection terminal disposed on the active surface;
a first molding layer that is disposed on the active surface and lower than the connection terminal; and
a second molding layer that is disposed on an outside of the active surface to surround the connection terminal and is higher than the first molding layer.

10. The chip level semiconductor package of claim 9, wherein a height of the second molding layer is equal to or smaller than a height of the connection terminal.

11. The chip level semiconductor package of claim 10, wherein the second molding layer is disposed on an edge of the substrate to constitute a wall surrounding the connection terminal.

12. The chip level semiconductor package of claim 9, further comprising a third molding layer covering the inactive surface.

13. A method of manufacturing a semiconductor package, comprising:
providing a substrate having an active surface and an inactive surface opposed to the active surface, and comprising a chip region and a dicing region;
forming a connection terminal on the active surface of the chip region;
forming a first molding layer exposing a portion of the connection terminal on the active surface of the chip region; and
forming a second molding layer having a different surface shape from the first molding layer so as to recognize a dicing line dividing the chip region on the active region of the dicing region.

14. The method of manufacturing a semiconductor package of claim 13, wherein forming the first and second molding layers are simultaneously performed.

15. The method of manufacturing a semiconductor package of claim 13, wherein forming the first molding layer includes forming a molding layer with a flat top surface lower than a top surface of the second molding layer.

16. The method of manufacturing a semiconductor package of claim 13, wherein forming the second molding layer includes forming a molding layer with an irregular top surface higher than a top surface of the first molding layer.

17. The method of manufacturing a semiconductor package of claim 16, wherein forming the second molding layer includes forming a molding layer with protrusions higher than the first molding layer and a groove defining a dicing line between the protrusions.

18. The method of manufacturing a semiconductor package of claim 17, wherein forming the second molding layer includes forming the protrusions to be as high as or lower than the connection terminal.

19. The method of manufacturing a semiconductor package of claim 13, further comprising dicing the substrate along the dicing region.

20. The method of manufacturing a semiconductor package of claim 19, wherein dicing the substrate comprises:
dividing the substrate into a plurality of unit substrates each having the chip regions; and
dividing the second molding layer along the dicing regions to form a supporter surrounding the chip region outside the plurality of respective unit substrates.

21. The method of manufacturing a semiconductor package of claim 13, further comprising a third molding layer covering the inactive surface.

22. An apparatus for manufacturing a semiconductor package, the apparatus comprising:
a first mold die comprising a first recessed inner face that constitutes a first cavity into which a first molding material is provided and includes a flat side and an irregular side, wherein a first tape is provided on the first recessed inner face; and
a second mold die coupled to the first molding die.

23. The apparatus for manufacturing a semiconductor package of claim 22, wherein a semiconductor package dividing into a chip region and a dicing region is interposed between the first and second mold dies so that a first molding layer having a flat top surface is formed on an active surface of the chip region by the flat side of the first recessed inner face, and a second molding layer having an irregular top surface higher than the first molding layer is formed on an active surface of a dicing region by the irregular side of the first recessed inner face.

24. The apparatus for manufacturing a semiconductor package of claim 22, further comprising a third mold die attachable to the first mold die, wherein the first recessed inner face is disposed on the third mold die.

25. The apparatus for manufacturing a semiconductor package of claim 24, wherein the first mold die further comprises an attaching portion into which the third mold die is fixedly inserted.

26. The apparatus for manufacturing a semiconductor package of claim 22, wherein the irregular side includes a groove aligned with the dicing region of the semiconductor package.

27. The apparatus for manufacturing a semiconductor package of claim 26, wherein a connection terminal is included in the chip region of the semiconductor package and a portion of the connection terminal sinks into the first tape.

28. The apparatus for manufacturing a semiconductor package of claim 27, wherein the first tape has a thickness equal to or greater than a sinking depth of the connection terminal.

29. The apparatus for manufacturing a semiconductor package of claim 26, wherein a connection terminal is included in the chip region of the semiconductor package and the irregular side further includes a dent into which a portion of the connection terminal sinks.

30. The apparatus for manufacturing a semiconductor package of claim 29, wherein the first tape has a thickness that is smaller than a depth of the dent.

31. The apparatus for manufacturing a semiconductor package of claim 30, wherein the depth of the dent is equal to or lower than a depth of the groove.

32. The apparatus for manufacturing a semiconductor package of claim 22, wherein the first mold die includes a first vacuum hole absorbing the first tape.

33. The apparatus for manufacturing a semiconductor package of claim 22, further comprising a first injection portion injecting the first molding material to the first cavity.

34. The apparatus for manufacturing a semiconductor package of claim 23, wherein the second mold die further includes a second recessed inner face into which a second tape is provided and constitutes a second cavity into which a second molding material is provided.

35. The apparatus for manufacturing a semiconductor package of claim 34, wherein a third molding layer is formed on an inactive surface opposed to the active surface of the semiconductor package by the second recessed inner face.

36. The apparatus for manufacturing a semiconductor package of claim 34, wherein the second tape has a thickness equal to or smaller than the thickness of the first tape.

37. The apparatus for manufacturing a semiconductor package of claim 34, wherein the second mold die further includes a second vacuum hole absorbing the second tape.

38. The apparatus for manufacturing a semiconductor package of claim 34, further comprising a first injecting portion providing the first molding material to the first cavity and a second injecting portion providing the second molding material to the second cavity.

39. The apparatus for manufacturing a semiconductor package of claim 22, wherein at least one of the first and second mold dies can be heated.

40. A method of manufacturing a semiconductor package, the method comprising:
providing a first mold die including a first recessed inner face constituting a first cavity into which a first molding material is provided, the first recessed inner face having a flat side and an irregular side;
providing a second mold die facing the first mold die;
providing a semiconductor package between the first and second mold dies;
providing the first molding material to the first cavity;
forming a first molding layer having a top surface of a uniform height on an active surface of a chip region of the semiconductor package through the first molding material provided into the flat side of the first recessed inner face; and
forming a second molding layer having a top surface of an irregular height greater than the first molding layer on an active surface of a dicing region of the semiconductor package through the first molding material provided into the irregular side of the first recessed inner face.

41. The method of manufacturing a semiconductor package of claim 40, wherein forming the second molding layer comprises forming a molding layer of a concavo-convex shape including protrusions that is higher than the first molding layer and a groove defining a dicing line between the protrusions.

42. The method of manufacturing a semiconductor package of claim 40, further comprising providing a first tape that can be bent along the flat and irregular sides to the first recessed inner face.

43. The method of manufacturing a semiconductor package of claim 40, wherein the second mold die further comprises a second recessed inner face constituting a second cavity into which a second molding material is provided.

44. The method of manufacturing a semiconductor package of claim 43, further comprising:
providing the second molding material to the second cavity; and
forming a third molding layer on an inactive surface of the semiconductor package.

45. The method of manufacturing a semiconductor package of claim 44, further comprising:
providing a first tape that can be bent along the flat and irregular sides to the first recessed inner face; and
providing a second tape to the second recessed inner face.

46. The method of manufacturing a semiconductor package of claim 45, wherein a thickness of the second tape is equal to or smaller than a thickness of the first tape.

47. An electronic device including the semiconductor package of claim 9.

48. An electronic device including the semiconductor package manufactured using the method of claim 13.

49. An electronic device including the semiconductor package manufactured using the method of claim 19.

50. An electronic device including the semiconductor package manufactured using the apparatus of claim 22.

51. An electronic device including the semiconductor package manufactured using the apparatus of claim 34.

52. An electronic device including the semiconductor package manufactured using the method of claim 40.

53. An electronic device including the semiconductor package manufactured using the method of claim 44.
